(19) United States
(12) Patent Application Publication
(10) Pub. No.: US 2014/0232004 A1
(43) Pub. Date: Aug. 21, 2014

(54) SEMICONDUCTOR DEVICE

(71) Applicant: MITSUBISHI ELECTRIC CORPORATION, Tokyo (JP)

(72) Inventors: Yasuhiro YOSHIURA, Tokyo (JP); Masayoshi TARUTANI, Tokyo (JP); Eiko OTSUKI, Tokyo (JP)

(73) Assignee: MITSUBISHI ELECTRIC CORPORATION, Tokyo (JP)

(21) Appl. No.: 14/062,619

(22) Filed: Oct. 24, 2013

(30) Foreign Application Priority Data
Feb. 18, 2013 (JP) 2013-028540

(51) Int. Cl. H01L 23/498

(52) U.S. Cl. CPC H01L 23/49805; H01L 23/49866
USPC 257/763

(57) ABSTRACT

The present invention includes a semiconductor substrate and a back electrode (a back multilayer electrode in the preferred embodiment) provided on a back surface of the semiconductor substrate. A rough source pattern is formed in a peripheral edge portion of the back surface of the semiconductor substrate which faces the back multilayer electrode.

### BACKGROUND OF THE INVENTION

1. Field of the Invention

The present invention relates to a semiconductor device and more particularly to a semiconductor device including a back electrode.

2. Description of the Background Art

In a power semiconductor chip for driving large current, generally, a metal film is formed on a back side of a semiconductor substrate, so that an electrode structure is provided.

For example, in n-type silicon (Si) to be used for a diode, an electrode using titanium (Ti) on a back side of a silicon substrate is formed (see Japanese Patent Application Laid-Open No. 2004-103919). A titanium layer is bonded to a silicon layer, so that an ohmic contact property can be enhanced. Consequently, it is possible to obtain a characteristic having low VF (a low forward voltage) and a low resistance. For the back electrode, an overall electrode (a metal) having no pattern is used generally.

### SUMMARY OF THE INVENTION

It is an object of the present invention to provide a semiconductor device capable of enhancing a bonding strength of a semiconductor substrate and a back electrode while maintaining an electrical characteristic of the semiconductor device.

A semiconductor device according to an aspect of the present invention includes a semiconductor substrate and a back electrode provided on a back surface of the semiconductor substrate. A rough surface pattern is formed in a peripheral edge portion of the back surface of the semiconductor substrate which faces the back electrode.

A semiconductor device according to another aspect of the present invention includes a semiconductor substrate and a back electrode provided on a back surface of the semiconductor substrate. A silicide layer is formed in a peripheral edge portion of the back surface of the semiconductor substrate which faces the back electrode.

According to the aspects of the present invention, a bonding strength between the back electrode and the semiconductor substrate can be increased.

Moreover, a region in which the rough surface pattern or the silicide layer is formed is restricted to the peripheral edge portion of the back surface of the semiconductor substrate. Therefore, an electrical characteristic of the semiconductor substrate can be prevented from being deteriorated.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing a structure of a semiconductor device according to the present preferred embodiment of the present invention;

FIG. 2 is a front view showing a back surface of a semiconductor substrate according to the preferred embodiment of the present invention;

FIG. 3 is a sectional view showing a structure of a semiconductor device according to the present preferred embodiment of the present invention;

FIG. 4 is a front view showing a back surface of a semiconductor substrate according to the preferred embodiment of the present invention; and

FIG. 5 is a sectional view showing a structure of a semiconductor device according to the technical premise of the present invention.

### DESCRIPTION OF THE PREFERRED EMBODIMENTS

Preferred embodiments according to the present invention will be described below with reference to the accompanying drawings.

Although a term, for example, a surface, a back surface or the like is used in the present specification, the term is used for distinguishing respective surfaces for convenience and is not related to actual vertical and transverse directions.

FIG. 5 is a sectional view showing a structure of a semiconductor device 101 according to the technical premise of the present invention.

As shown in FIG. 5, the semiconductor device 101 includes a back multilayer electrode 1, a semiconductor substrate 2 provided on the back multilayer electrode 1, and an element region 3 provided on the semiconductor substrate 2.

The back multilayer electrode 1 is a metal electrode formed by stacking a plurality of types of metal layers. It is desirable that any of the metal layers which is provided in contact with the semiconductor substrate 2 should be constituted by titanium. The back electrode may have a single layer.

The semiconductor substrate 2 is constituted by silicon to be a semiconductor having a first conductivity type (for example, an n type), silicon carbide or the like.

The element region 3 includes a semiconductor layer having a second conductivity type (for example, a p type) and is formed by execution of ion implantation into a surface of a drift layer which is provided on the semiconductor substrate 2 or the like.

A structure of a semiconductor device in which bond between the semiconductor substrate 2 and the back multilayer electrode 1 can be strengthened and an electrical characteristic of the semiconductor device can be maintained will be described in the following preferred embodiments.

### FIRST EMBODIMENT

### Structure

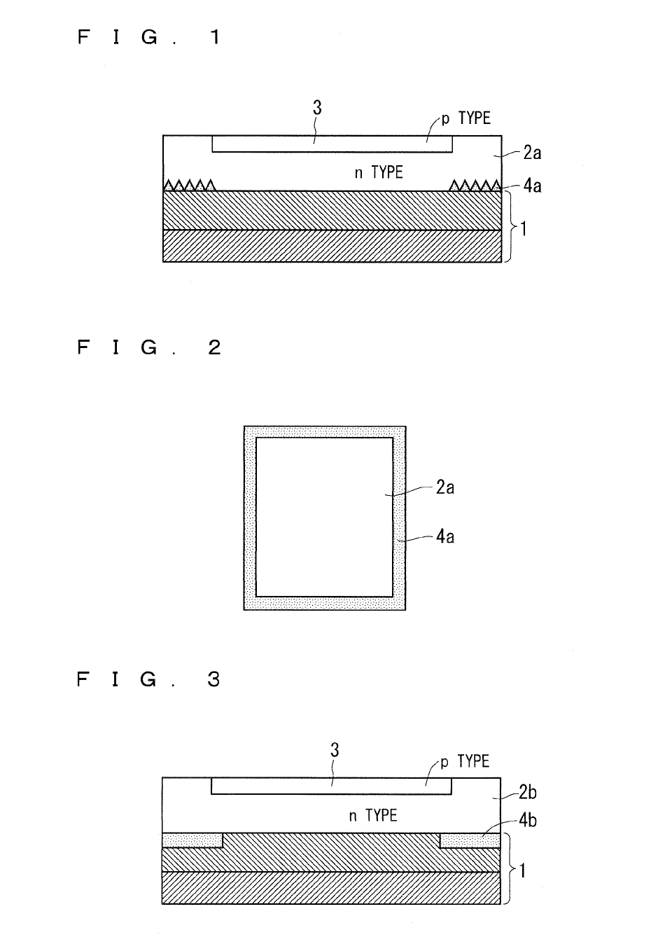

FIG. 1 is a sectional view showing a structure of a semiconductor device 100a according to the present preferred embodiment of the present invention.

As shown in FIG. 1, the semiconductor device 100a includes a back multilayer electrode 1, a semiconductor substrate 2a provided on the back multilayer electrode 1, and an element region 3 provided on the semiconductor substrate 2a. Since structures having the same reference numerals as those in the semiconductor device 101 shown in FIG. 5 are the same as those in the case described above, detailed description will be omitted.

The semiconductor substrate 2a has a rough surface pattern 4a formed on a back surface which is provided in contact with the back multilayer electrode 1. The rough surface pattern 4a is formed by execution of surface roughening over the back surface of the semiconductor substrate 2a.

The rough surface pattern 4a is formed in a peripheral edge portion of the back surface as shown in a front view illustrating the back surface of the semiconductor substrate 2a in FIG. 2. Although the rough surface pattern 4a is formed over the whole peripheral edge portion of the back surface as shown in FIG. 2, the rough surface pattern 4a may be formed in a part of the peripheral edge portion.

In the semiconductor device 101 shown in FIG. 5, the rough surface pattern 4a is not formed on the back surface of the semiconductor substrate 2. Therefore, when a thermal process (200° C. or more) is carried out, for example, a stress is generated due to a difference between a coefficient of thermal expansion of the back multilayer electrode 1 and that of the semiconductor substrate 2, so that peeling between the back multilayer electrode 1 and the semiconductor substrate 2 occurs.

On the other hand, in the semiconductor device 100a shown in FIG. 1, the rough surface pattern 4a is formed in the peripheral edge portion of the back surface of the semiconductor substrate 2a. In a region in which the rough surface pattern 4a is formed, a contact area in which the back multilayer electrode 1 and the semiconductor substrate 2a come in contact with each other is increased. Therefore, a bonding strength between the back multilayer electrode 1 and the semiconductor substrate 2a can be increased.

The bonding strength between the back multilayer electrode 1 and the semiconductor substrate 2a is increased in the peripheral edge portion of the back surface which can be a starting point of the peeling between both of the members. Also in the case where the thermal process or the like is carried out, therefore, it is possible to suppress the occurrence of the peeling between both of the members.

Moreover, the region in which the rough surface pattern 4a is formed is restricted to the peripheral edge portion of the back surface of the semiconductor substrate 2a. For this reason, an electrical characteristic between the back multilayer electrode 1 and the semiconductor substrate 2a is prevented from being deteriorated by the rough surface pattern 4a in a central part (which corresponds to the element region 3 on the surface) of the back surface of the semiconductor substrate 2a. Consequently, it is possible to maintain the electrical characteristic of the semiconductor device without deterioration (increase in resistance, a main withstand voltage leakage or the like).

### Effect

According to the preferred embodiment of the present invention, the semiconductor device includes the semiconductor substrate 2a and the back electrode provided on the back surface of the semiconductor substrate 2a (the back multilayer electrode 1 in the preferred embodiment).

Moreover, the rough surface pattern 4a is formed in the peripheral edge portion of the back surface of the semiconductor substrate 2a which faces the back multilayer electrode 1.

According to the structure, the contact area in which the back multilayer electrode 1 and the semiconductor substrate 2a come in contact with each other is increased in the region in which the rough surface pattern 4a is formed. Therefore, the bonding strength between the back multilayer electrode 1 and the semiconductor substrate 2a can be increased.

Moreover, the region in which the rough surface pattern 4a is formed is restricted to the peripheral edge portion of the back surface of the semiconductor substrate 2a. Therefore, the electrical characteristic can be prevented from being deteriorated in the central part (which corresponds to the element region 3 on the surface) of the back surface of the semiconductor substrate 2a.

According to the preferred embodiment of the present invention, furthermore, the surface of the back multilayer electrode 1 which is provided in contact with the semiconductor substrate 2a is formed of titanium.

According to the structure, the bonding strength between the back multilayer electrode 1 and the semiconductor substrate 2a is increased by the rough surface pattern 4a. Also in the case where the bond is formed by using titanium having comparatively small bonding force, therefore, it is possible to obtain a sufficient bonding strength.

According to the preferred embodiment of the present invention, moreover, the back multilayer electrode 1 is formed by a plurality of different metal layers.

According to the structure, it is possible to prevent a warpage from being caused by thin finishing. Thus, it is possible to enhance quality of the semiconductor device.

### SECOND EMBODIMENT

### Structure

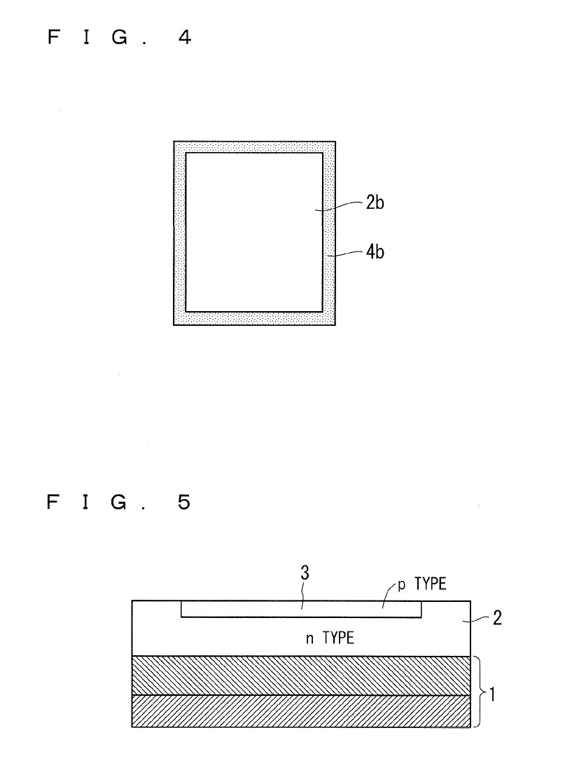

FIG. 3 is a sectional view showing a structure of a semiconductor device 100b according to the present preferred embodiment of the present invention.

As shown in FIG. 3, the semiconductor device 100b includes a back multilayer electrode 1, a semiconductor substrate 2b provided on the back multilayer electrode 1, and an element region 3 provided on the semiconductor substrate 2b. Since structures having the same reference numerals as those in the semiconductor device 101 shown in FIG. 5 are the same as those in the case described above, detailed description will be omitted.

The semiconductor substrate 2b has a silicide layer 4b formed on a back surface which is provided in contact with the back multilayer electrode 1. The silicide layer 4b is formed by execution of silicide formation processing at a comparatively low temperature of 450° C. or less, for example. As a metal to be used for the silicide layer 4b, Al, Co, Ni or the like is employed, for example.

The silicide layer 4b is formed in a peripheral edge portion of the back surface as shown in a front view illustrating the back surface of the semiconductor substrate 2b in FIG. 4. Here, although the silicide layer 4b may be formed over the whole peripheral edge portion of the back surface as shown in FIG. 4, the silicide layer 4b may be formed in a part of the peripheral edge portion.

In the semiconductor device 101 shown in FIG. 5, the silicide layer 4b is not formed on the back surface of the semiconductor substrate 2. Therefore, when a thermal process (200° C. or more) is carried out, for example, a stress is generated due to a difference between a coefficient of thermal expansion of the back multilayer electrode 1 and that of the semiconductor substrate 2, so that peeling between the back multilayer electrode 1 and the semiconductor substrate 2 occurs.

On the other hand, in the semiconductor device 100b shown in FIG. 3, the silicide layer 4b is formed in the peripheral edge portion of the back surface of the semiconductor substrate 2b. In a region in which the silicide layer 4b is formed, the back multilayer electrode 1 and the semiconductor substrate 2b are bonded to each other through the silicide layer 4b. Therefore, a bonding strength between the back multilayer electrode 1 and the semiconductor substrate 2b can be increased.

The bonding strength between the back multilayer electrode 1 and the semiconductor substrate 2b is increased in the peripheral edge portion of the back surface which can be a starting point of the peeling between both of the members. Also in the case where the thermal process or the like is carried out, therefore, it is possible to suppress the occurrence of the peeling between both of the members.

Moreover, the region in which the silicide layer 4b is formed is restricted to the peripheral edge portion of the back surface of the semiconductor substrate 2b. For this reason, an electrical characteristic between the back multilayer electrode 1 and the semiconductor substrate 2b is prevented from being deteriorated by the silicide layer 4b in a central part which corresponds to the element region 3 on the surface of the back surface of the semiconductor substrate 2b. Consequently, it is possible to maintain an electrical characteristic of the semiconductor device without deterioration (increase in a resistance, a main withstand voltage leakage or the like).

### Effect

According to the preferred embodiment of the present invention, the semiconductor device includes the semiconductor substrate 2b and the back electrode (the back multilayer electrode 1 in the preferred embodiment) provided on the back surface of the semiconductor substrate 2b.

Moreover, the silicide layer 4b is formed in the peripheral edge portion of the back surface of the semiconductor substrate 2b which faces the back multilayer electrode 1.

According to the structure, the contact area in which the back multilayer electrode 1 and the semiconductor substrate 2b come in contact with each other is increased in the region in which the silicide layer 4b is formed. Therefore, the bonding strength between the back multilayer electrode 1 and the semiconductor substrate 2b can be increased.

Moreover, the region in which the silicide layer 4b is formed is restricted to the peripheral edge portion of the back surface of the semiconductor substrate 2b. Therefore, the electrical characteristic can be prevented from being deteriorated in the central part (which corresponds to the element region 3 on the surface) of the back surface of the semiconductor substrate 2b.

According to the preferred embodiment of the present invention, moreover, the silicide layer 4b is constituted by silicide using Al, Co or Ni.

According to the structure, it is possible to form the silicide layer by the silicide formation processing at a comparatively low temperature of 450° C. or less, for example. Thus, a manufacturing process can easily be carried out.

According to the preferred embodiment of the present invention, furthermore, the surface of the back multilayer electrode 1 which comes in contact with the semiconductor substrate 2b is formed of titanium.

According to the structure, the bonding strength between the back multilayer electrode 1 and the semiconductor substrate 2b is increased by the silicide layer 4b. Also in the case where the bond is formed by using titanium having comparatively small bonding force, therefore, it is possible to obtain a sufficient bonding strength.

According to the preferred embodiment of the present invention, moreover, the back multilayer electrode 1 is formed by a plurality of different metal layers.

According to the structure, it is possible to prevent a warpage from being caused by thin finishing. Thus, it is possible to enhance quality of the semiconductor device.

Although quality of materials and the materials of the respective components, executing conditions and the like are also described in the preferred embodiments according to the present invention, these are illustrative and are not restricted to the description.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor substrate; and
a back electrode provided on a back surface of said semiconductor substrate;
wherein a rough surface pattern is formed in a peripheral edge portion of said back surface of said semiconductor substrate which faces said back electrode.

2. The semiconductor device according to claim 1, wherein a surface of said back electrode which is provided in contact with said semiconductor substrate is formed of titanium.

3. The semiconductor device according to claim 1, wherein said back electrode is constituted by a plurality of different metal layers.

4. A semiconductor device comprising:
a semiconductor substrate; and
a back electrode provided on a back surface of said semiconductor substrate;
wherein a silicide layer is formed in a peripheral edge portion of said back surface of said semiconductor substrate which faces said back electrode.

5. The semiconductor device according to claim 4, wherein said silicide layer is constituted by silicide using Al, Co or Ni.

6. The semiconductor device according to claim 4, wherein a surface of said back electrode which is provided in contact with said semiconductor substrate is formed of titanium.

7. The semiconductor device according to claim 4, wherein said back electrode is constituted by a plurality of different metal layers.
